(19) United States
(12) Patent Application Publication
(10) Pub. No.: US 2017/0266943 A1
(43) Pub. Date: Sep. 21, 2017

(54) SUBSTRATE SUCTION DEVICE, SUBSTRATE BONDING DEVICE, SUBSTRATE BONDING METHOD, AND ELECTRONIC DEVICE MANUFACTURING METHOD

(71) Applicant: ASAHI GLASS COMPANY, LIMITED, Chiyoda-ku (JP)

(72) Inventors: Hiroshi UTSUGI, Tokyo (JP); Yasunori ITO, Tokyo (JP)

(73) Assignee: ASAHI GLASS COMPANY, LIMITED, Chiyoda-ku (JP)

(21) Appl. No.: 15/497,960

(22) Filed: Apr. 26, 2017

Related U.S. Application Data
(63) Continuation of application No. PCT/JP2015/080023, filed on Oct. 23, 2015.

(30) Foreign Application Priority Data
Oct. 29, 2014 (JP) 2014-220107

(51) Int. Cl. B32B 38/18; B32B 17/00; H01L 21/683; B32B 37/10; B32B 37/18; B32B 7/12; B32B 27/00

(52) U.S. Cl. CPC B32B 38/1858; B32B 7/12; B32B 17/00; B32B 27/00; B32B 37/10; B32B 37/182; H01L 21/6838; B32B 2315/08; B32B 2457/20

(57) ABSTRACT

A substrate suctioning device includes a table having a suction surface suctioning a substrate, and a plurality of suction units provided on the suction surface of the table. The substrate suctioning device includes a control unit that, with setting a group of suction unit(s) among the plurality of suction units as a starting point, sequentially decompresses a plurality of remaining suction units disposed in a direction away from the group of suction unit(s) as the starting point, along the direction away from the group of suction unit(s) as the starting point.

### TECHNICAL FIELD

The present invention relates to a substrate suctioning device, a bonding device and a bonding method of a substrate, and an electronic device manufacturing method.

### BACKGROUND ART

With a reduction in sheet-thickness and weight of electronic devices such as a display panel, a solar cell and a thin film secondary battery, a substrate (first substrate) such as a glass sheet, a resin sheet and a metallic sheet, which are used in the electronic devices, are demanded to be a thinner sheet.

However, when the thickness of the substrate becomes small, handleability of the substrate gets worse. Therefore, it is difficult to form a function layer (thin film transistor (TFT) and a color filter (CF)) for an electronic device on a surface of the substrate.

Accordingly, there is suggested an electronic device manufacturing method in which a reinforcing plate (second substrate) is bonded to a rear surface of the substrate to manufacture a laminate, in which the substrate is reinforced by the reinforcing plate, and a function layer is formed on a front surface of the substrate in a state of the laminate (for example, refer to PTL 1). In this manufacturing method, the handleability of the substrate is improved, and thus it is possible to form the function layer on the surface of the substrate in a satisfactory manner. In addition, the reinforcing plate is peeled-off from the substrate after formation of the function layer.

PTL 2 discloses a bonding device that bonds a substrate and a reinforcing plate.

The bonding device disclosed in PTL 2 includes an upper table that suctions the substrate on a lower surface thereof, and a lower table which is disposed on a lower side of the upper table and in which the reinforcing plate is placed on an upper surface of the lower table. In addition, the device includes a rotating roller that comes into contact with a lower surface of the reinforcing plate placed on the lower table to allow the reinforcing plate to be bending-deformed with its own weight, a pressing cylinder that presses the reinforcing plate, which has been bending-deformed due to the rotating roller, against the substrate that is suctioned to the upper table, a movement mechanism that moves the rotating roller and the pressing cylinder with respect to a lower surface of the upper table.

According to the bonding device of PTL 2, first, the substrate is suctioned to the upper table, and the reinforcing plate is placed on the lower table. Next, the rotating roller is raised by the pressing cylinder to bring the rotating roller into contact with the lower surface of the reinforcing plate. Then, the rotating roller is further raised to allow the reinforcing plate to be bending-deformed with its own weight, and presses the reinforcing plate to the substrate in this state. Next, the rotating roller and the pressing cylinder are moved by the movement mechanism to bond the reinforcing plate to the substrate.

According to the bonding device of PTL 2, the reinforcing plate is bonded to the substrate in a bending-deformed state. Therefore, air bubbles are less likely to be entrapped between the substrate and the reinforcing plate. In addition, the reinforcing plate is not suction-fixed, and thus it is possible to bond the reinforcing plate and the substrate in a state in which a strain of the reinforcing plate is small. According to this, it is possible to reduce warpage of a laminate that occurs after bonding.

The lower surface of the upper table in PTL 2, that is, a suction surface is first inverted to face an upper side before receiving a substrate that is conveyed from a transport mechanism. Then, when the substrate is transferred to and placed on heads of a plurality of rods that protrude from the suction surface, the rods are contracted to retreat from the suction surface. By this movement, the substrate is placed on the suction surface, and an inner pressure of a plurality of suction holes provided in the suction surface is then reduced by a suction source. Through the above-described movement, the substrate is suctioned and retained on the suction surface of the table.

### CITATION LIST

### Patent Literature

PTL 1: JP-A-2007-326358

PTL 2: JP-A-2013-155053

### SUMMARY OF INVENTION

### Technical Problem

The bonding device of PTL 2 can attain an improvement with respect to warpage of a laminate, which is caused by bonding, due to an action of the rotating roller that allows the reinforcing plate to be bending-deformed with its own weight. However, for example, when placing a thin substrate having a thickness of 0.2 mm or less on the upper table, the substrate may be placed (also referred to as “multi-point placing”) on the table in a warped state due to warpage of the thin substrate itself, and warpage due to its own weight of the substrate which occurs when the substrate is placed on the head of the rods. In this case, even when the substrate is suctioned to the suction surface of the upper table, the whole surface of the substrate does not conform to the suction surface, and the substrate may partially come off the suction surface. In a case where suction is partially not accomplished, a strain remains in a laminate after bonding, and thus there is a problem that warpage occurs in the laminate.

The present invention has been made in consideration of the above-described problems, and an object thereof is to provide a substrate suctioning device, a bonding device and a bonding method of a substrate, and an electronic device manufacturing method, which are capable of reducing warpage of a laminate after bonding by improving a substrate suction type with respect to a table.

### Solution to Problem

To accomplish the object, an aspect of the substrate suctioning device of the present invention is a substrate suctioning device including a table having a suction surface suctioning a substrate, and a plurality of suction units provided on the suction surface of the table, in which the device includes a control unit that, with setting a group of suction unit(s) among the plurality of suction units as a starting point, sequentially decompresses a plurality of remaining suction units disposed in a direction away from the group of suction unit(s) as the starting point, along the direction away.

According to this aspect of the present invention, when the substrate is placed on the suction surface of the table, the control unit, with setting a group of suction unit(s) among the plurality of suction units as a starting point, sequentially decompresses the plurality of remaining suction units, which are disposed in a direction away from the group of suction unit(s), along the direction away. According to this, with setting a portion corresponding to the group of suction unit(s) as a starting point, the substrate is sequentially suctioned, while correcting warpage of the substrate itself to be flat, in a direction away from the portion, and the whole surface of the substrate is suctioned to the suction surface of the table. Accordingly, according to the aspect of the present invention, it is possible to improve a suction type of the substrate with respect to the table, and thus it is possible to reduce warpage of a laminate after bonding.

It is preferable that the control unit, with setting the group of suction unit(s) disposed in a central portion of the table having a rectangular shape as the starting point, sequentially decompresses the plurality of remaining suction units disposed in the direction away from the group of suction unit(s) set as the starting point, along the direction away.

According to this aspect of the present invention, the substrate is sequentially suctioned to the table in a ripple shape with the central portion of the substrate set as the starting point. The aspect of the present invention is a configuration where the plurality of suction units are divided into a plurality of suction regions, and are divided in a ripple shape around the central portion of the table. According to the aspect of the present invention, it is possible to suppress occurrence of a non-suctioned portion caused by a multi-point placing at initial placing at which the substrate is placed on the table.

It is preferable that the control unit, with setting the group of suction unit(s) disposed along one side portion of the table having a rectangular shape as the starting point, sequentially decompresses the plurality of remaining suction units disposed in the direction away from the group of suction unit(s) set as the starting point, along the direction away.

According to this aspect of the present invention, the substrate, with setting one side portion of the substrate as the starting point, is sequentially suctioned to the table in a direction away from the one side portion. The one side portion may be the whole region or a partial portion of the one side portion.

It is preferable that the plurality of suction units are also used as air spraying units, and among the plurality of suction units, a suction unit before driven by the control unit is switched to the air spraying unit by the control unit.

According to this aspect of the present invention, while the substrate is air-blown due to air that is sprayed from the suction unit, it is sequentially suctioned by the suction units that are switched into vacuum. According to this, it is possible to allow suction to proceed in a state of reducing friction (may be referred to as “friction of an initially placed portion”), which is friction between the suction surface of the table and the substrate and occurs in a case where the substrate is multi-point placed on the suction surface of the table.

To accomplish the above-described object, an aspect of the substrate bonding device of the present invention is a substrate bonding device that bonds a first substrate and a second substrate, including the substrate suctioning device according to the present invention, which suctions the first substrate by the table of the suctioning device, and a roller that presses the second substrate in a state of bending-deformed with its own weight, against the first substrate, and bonds a whole surface of the second substrate to the first substrate while rotating.

To accomplish the above-described object, an aspect of the substrate bonding method of the present invention is a substrate bonding method of bonding a first substrate and a second substrate via an adsorption layer, including a suction step of suctioning and retaining the first substrate to the table of the substrate suctioning device according to the present invention, and a bonding step of pressing the second substrate in a state of bending-deformed with its own weight, against the first substrate by a roller, and bonding a whole surface of the second substrate to the first substrate while rotating the roller.

According to this aspect of the present invention, it is possible to improve a suction type of the first substrate with respect to the table, and thus it is possible to reduce warpage of a laminate, which is caused by the suction step. In addition, even in the bonding step, it is possible to reduce warpage of the laminate, which is caused by the bonding step, due to an action of the rotating roller that allows the second substrate to be bending-deformed with its own weight.

To accomplish the above-described object, an aspect of the electronic device manufacturing method of the present invention includes a laminate manufacturing step of manufacturing a laminate by bonding a first substrate and a second substrate, a function layer forming step of forming a function layer on an exposed surface of the first substrate in the laminate, and a separation step of separating the second substrate from the first substrate on which the function layer has been formed, in which the laminate manufacturing step includes a suction step of suctioning and retaining the first substrate to the table of the suctioning device according to the present invention, and a bonding step of pressing the second substrate in a state of bending-deformed with its own weight, against the first substrate by a roller, and bonding a whole surface of the second substrate to the first substrate while rotating the roller.

According to this aspect of the present invention, the laminate manufacturing step of the electronic device manufacturing method includes the suction step and the bonding step according to the present invention. Accordingly, it is possible to provide an electronic device manufacturing method capable of reducing warpage of the laminate after bonding. In the laminate manufactured by the laminate manufacturing step, warpage is reduced. Accordingly, it is possible to form a function layer with good quality on an exposed surface of the first substrate in a function layer forming step.

### Advantageous Effects of Invention

According to the substrate suctioning device, the bonding device and the bonding method of a substrate, and the electronic device manufacturing method according to the present invention, it is possible to improve a suction type of the substrate with respect to the table, and thus it is possible to reduce warpage of the laminate after bonding.

### BRIEF DESCRIPTION OF DRAWINGS

FIG. 1 is a main-portion enlarged side view illustrating an example of a laminate to be provided to an electronic device manufacturing process.

FIG. 2 is a main-portion enlarged side view illustrating an example of a laminate prepared in during an LCD manufacturing process.

FIG. 3 (A) to (D) of FIG. 3 are side views illustrating a main-portion configuration of a bonding device used in a bonding step of a laminate manufacturing step.

FIG. 4 is a plan view of an upper table in which a substrate suctioning device of the present invention is applied to the upper table.

FIG. 5 is a structure diagram of the upper table which illustrates a vacuum system and an air blowing system of the upper table of FIG. 4.

FIG. 6 (A) of FIG. 6 is a side view of the upper table which illustrates a state immediately before a substrate 2 is placed on a suction surface of the upper table, and (B) of FIG. 6 is a side view of the upper table in which the substrate is placed on the suction surface of the upper table.

FIG. 7 (A) to (D) of FIG. 7 are explanatory views illustrating in time series that the substrate is sequentially suctioned onto the suction surface.

FIG. 8 is a plan view of the upper table which illustrates another aspect of the upper table.

FIG. 9 is a plan view of the upper table which illustrates still another aspect of the upper table.

### DESCRIPTION OF EMBODIMENTS

Hereinafter, an embodiment of the present invention will be described with reference to the accompanying drawings.

In the following description, description will be given of a case where a substrate suctioning device, and a bonding device and a bonding method of a substrate according to the present invention are used in an electronic device manufacturing process.

The electronic device represents an electronic component such as a display panel, a solar cell and a thin film secondary battery. Examples of the display panel includes liquid crystal display (LCD) panel, a plasma display panel (PDP) and an organic EL display (OELD: organic electro luminescence display) panel.

### [Electronic Device Manufacturing Process]

The electronic device is manufactured by forming a function layer (a thin film transistor (TFT) and a color filter (CF) in a case of the LCD) for the electronic device on a front surface of a substrate formed from glass, a resin, a metal, and the like.

The substrate is constituted as a laminate in which a rear surface thereof is bonded to a reinforcing plate before forming the function layer. Then, the function layer is formed on the front surface (exposed surface) of the substrate in the state of a laminate. In addition, after forming the function layer, the reinforcing plate is peeled-off from the substrate.

That is, electronic device manufacturing process include a laminate manufacturing step of manufacturing a laminate by bonding the substrate and the reinforcing plate to each other, a function layer forming step of forming a function layer on the front surface of the substrate in a state of the laminate, and a separating step of separating the reinforcing plate from the substrate on which the function layer has been formed. The substrate suctioning device, and the bonding device and the bonding method of a substrate according to the present invention are applied to the laminate manufacturing step.

### [Laminate 1]

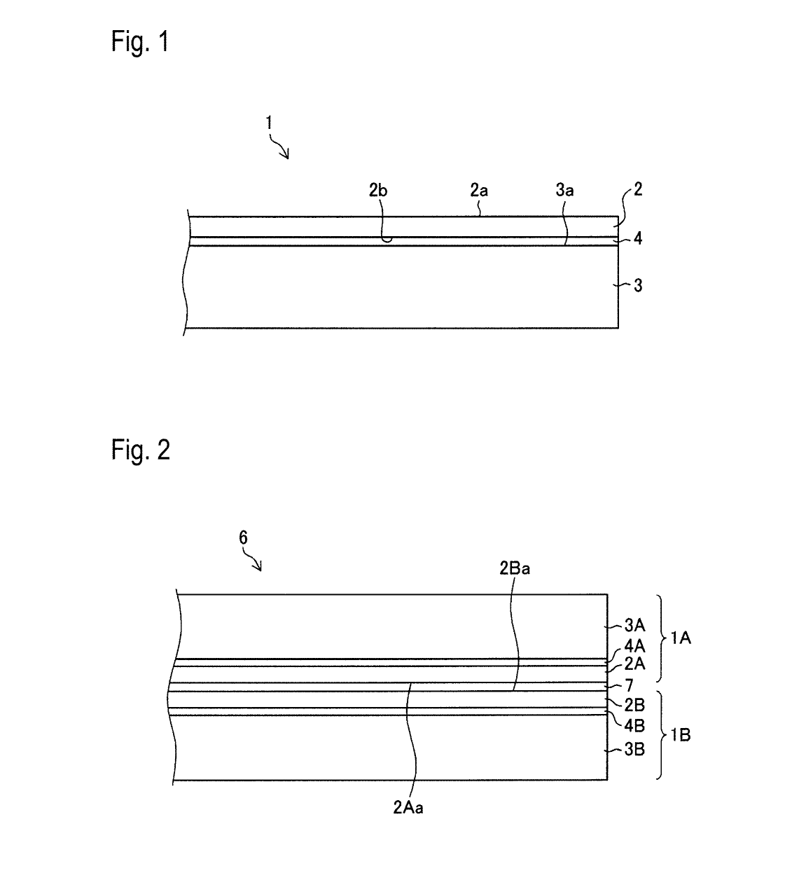

FIG. 1 is a main-portion enlarged side view illustrating an example of a laminate 1.

The laminate 1 includes a substrate (first substrate) 2 on which a function layer is formed, and a reinforcing plate (second substrate) 3 that reinforces the substrate 2. In addition, a reinforcing plate 3 includes, on a front surface 3a, a resin layer 4 as an adsorption layer, and a rear surface 2b of the substrate 2 is bonded to the resin layer 4. That is, the substrate 2 is bonded to the reinforcing plate 3 via the resin layer 4 in a peelable manner due to Van der Waals force that acts between the substrate 2 and the resin layer 4 or an adhesive force of the resin layer 4.

### [Substrate 2]

A function layer is formed on the front surface 2a of the substrate 2. Examples of the substrate 2 include a glass substrate, a ceramic substrate, a resin substrate, a metal substrate, and a semiconductor substrate. Among these substrates, the glass substrate is excellent in chemical resistance and humidity permeability resistance, and has a small coefficient of linear expansion, and accordingly, it is suitable as the substrate 2 for an electronic device. In addition, as the coefficient of linear expansion decreases, there is also an advantage that a pattern of the function layer, which is formed at a high temperature, is less likely to misaligned during cooling.

Examples of glass for the glass substrate include oxide-based glass containing silicon oxide as a main component, such as alkali-free glass, borosilicate glass, soda-lime glass, and high-silica glass. As the oxide-based glass, glass, in which the content of silicon oxide is 40 to 90 mass % in terms of an oxide, is preferable.

As the glass for the glass substrate, it is preferable to select and employ glass suitable for a kind of an electronic device to be manufactured, and glass suitable for a manufacturing process of the electronic device. For example, as the glass substrate for a liquid crystal panel, it is preferable to employ glass (alkali-free glass) that substantially does not contain an alkali-metal component.

The thickness of the substrate 2 is set in correspondence with the kind of the substrate 2. For example, in a case of employing the glass substrate for the substrate 2, the thickness thereof is set to preferably 0.7 mm or less, more preferably 0.3 mm or less, and still more preferably 0.1 mm or less for a reduction in weight and sheet-thickness of the electronic device. In a case where the thickness is 0.3 mm or less, it is possible to apply satisfactory flexible properties to the glass substrate. In addition, in a case where the thickness is 0.1 mm or less, the glass substrate can be wound in a roller shape. However, it is preferable that the thickness is 0.03 mm or greater from the viewpoint of manufacturing the glass substrate and from the viewpoint of handling of the glass substrate.

Furthermore, in FIG. 1, the substrate 2 is constituted by one sheet of substrate, but the substrate 2 may be constituted by a plurality of sheets of substrates. That is, the substrate 2 may be constituted as a laminate in which a plurality of sheets of the substrates are laminated.

### [Reinforcing Plate 3]

Examples of the reinforcing plate 3 include a glass substrate, a ceramic substrate, a resin substrate, a metal substrate, and a semiconductor substrate.

The thickness of the reinforcing plate 3 is set to 0.7 mm or less, and is set in correspondence with the kind, the thickness and the like of the substrate 2 to be reinforced. The thickness of the reinforcing plate 3 may be greater or smaller than that of the substrate 2, and is preferably 0.4 mm or greater so as to reinforce the substrate 2.

Furthermore, in this example, the reinforcing plate 3 is constituted by one sheet of substrate, but the reinforcing plate 3 may be constituted as a laminate in which a plurality of sheets of substrates are laminated.

### [Resin Layer 4]

A bonding force between the resin layer 4 and the reinforcing plate 3 is set to be higher than a bonding force between the resin layer 4 and the substrate 2 so as to prevent peeling-off between the resin layer 4 and the reinforcing plate 3. According to this, in a peeling-off step, an interface between the resin layer 4 and the substrate 2 is peeled off.

A resin that constitutes the resin layer 4 is not particularly limited, and examples thereof include an acrylic resin, a polyolefin resin, a polyurethane resin, a polyimide resin, a silicone resin, and a polyimide silicone resin. Several kinds of resins may be mixed and used. Among those, the silicone resin and the polyimide silicone resin are preferable from the viewpoint of heat resistance or peeling properties.

The thickness of the resin layer 4 is not particularly limited, and is preferably set to 1 to 50 μm, and is more preferably set to 4 to 20 μm. In a case where the thickness of the resin layer 4 is set to 1 μm or greater, when air bubbles or foreign matters are mixed-in between the resin layer 4 and the substrate 2, it is possible to absorb the thickness of the air bubbles or the foreign matters through deformation of the resin layer 4. On the other hand, in a case where the thickness of the resin layer 4 is set to 50 μm or less, it is possible to shorten formation time of the resin layer 4, and a resin of the resin layer 4 is not used more than necessary. Accordingly, this case is economical.

It is preferable that an outer shape of the resin layer 4 is the same as an outer shape of the reinforcing plate 3 or smaller than the outer shape of the reinforcing plate 3 in order for the reinforcing plate 3 to support the entirety of the resin layer 4. In addition, it is preferable that the outer shape of the resin layer 4 is the same as an outer shape of the substrate 2 or larger than the outer shape of the substrate 2 in order for the resin layer 4 to come into close contact with the entirety of the substrate 2.

In addition, in FIG. 1, the resin layer 4 is constituted by one layer, but the resin layer 4 may be constituted by two or greater layers. In this case, the total thickness of the all layers, which constitute the resin layer 4, becomes the thickness of the resin layer. In addition, in this case, the kinds of resins, which constitute the each of the layers, may be different from each other.

In addition, in this embodiment, the resin layer 4, which is an organic film, is used as the adsorption layer, but an inorganic layer may be used instead of the resin layer 4. For example, the inorganic film, which constitutes the inorganic layer, includes at least one kind selected from the group consisting of a metal silicide, a nitride, a carbide, and a carbonitride.

In addition, the laminate 1 in FIG. 1 includes the resin layer 4 as the adsorption layer, but may be constituted of the substrate 2 and the reinforcing plate 3 without the resin layer 4. In this case, the substrate 2 and the reinforcing plate 3 are bonded to each other in a peelable manner by, for example, Van deer Waals force that acts between the substrate 2 and the reinforcing plate 3. In addition, in this case, it is preferable to form an inorganic thin film on the front surface 3a of the reinforcing plate 3 so that the substrate 2 that is a glass substrate and the reinforcing plate 3 that is a glass plate do not adhere to each other at a high temperature.

[Laminate 6 of Embodiment in which Function Layer is Formed]

A function layer is formed on the front surface 2a of the substrate 2 in the laminate 1 through a function layer forming step. As a function layer forming method, a deposition method such as a CVD (chemical vapor deposition) method or a PVD (physical vapor deposition) method, or a sputtering method are used. The function layer is formed into a predetermined pattern by a photolithographic method or an etching method.

FIG. 2 is a main-portion enlarged side view illustrating an example of a rectangular laminate 6 manufactured during an LCD manufacturing process.

The laminate 6 is constituted by a reinforcing plate 3A, a resin layer 4A, a substrate 2A, a function layer 7, a substrate 2B, a resin layer 4B, and a reinforcing plate 3B, which are laminated in this order. That is, the laminate 6 in FIG. 2 corresponds to a laminate in which the laminates 1 illustrated in FIG. 1 are symmetrically disposed with the function layer 7 interposed therebetween. Hereinafter, a laminate, which is constituted by the substrate 2A, the resin layer 4A and the reinforcing plate 3A, is referred to as a first laminate 1A, and a laminate, which is constituted by the substrate 2B, the resin layer 4B and the reinforcing plate 3B, is referred to as a second laminate 1B.

A thin film transistor (TFT) as the function layer 7 is formed on a front surface 2Aa of the substrate 2A in the first laminate 1A, and a color filter (CF) as the function layer 7 is formed on a front surface 2Ba of the substrate 2B in the second laminate 1B.

The first laminate 1A and second laminate 1B are integrated with each other in such a manner that front surfaces 2Aa and 2Ba of the substrates 2A and 2B overlap each other. According to this, the laminate 6, which has a structure in which the first laminate 1A and the second laminate 1B are symmetrically disposed with the function layer 7 interposed therebetween, is manufactured.

In the laminate 6, after a peeling initiation portion is formed at an interface by a knife tip in a separation step, the reinforcing plates 3A and 3B are sequentially peeled off, and a polarization plate, a backlight and the like are mounted to manufacture an LCD as a product.

### [Bonding Device of Embodiment]

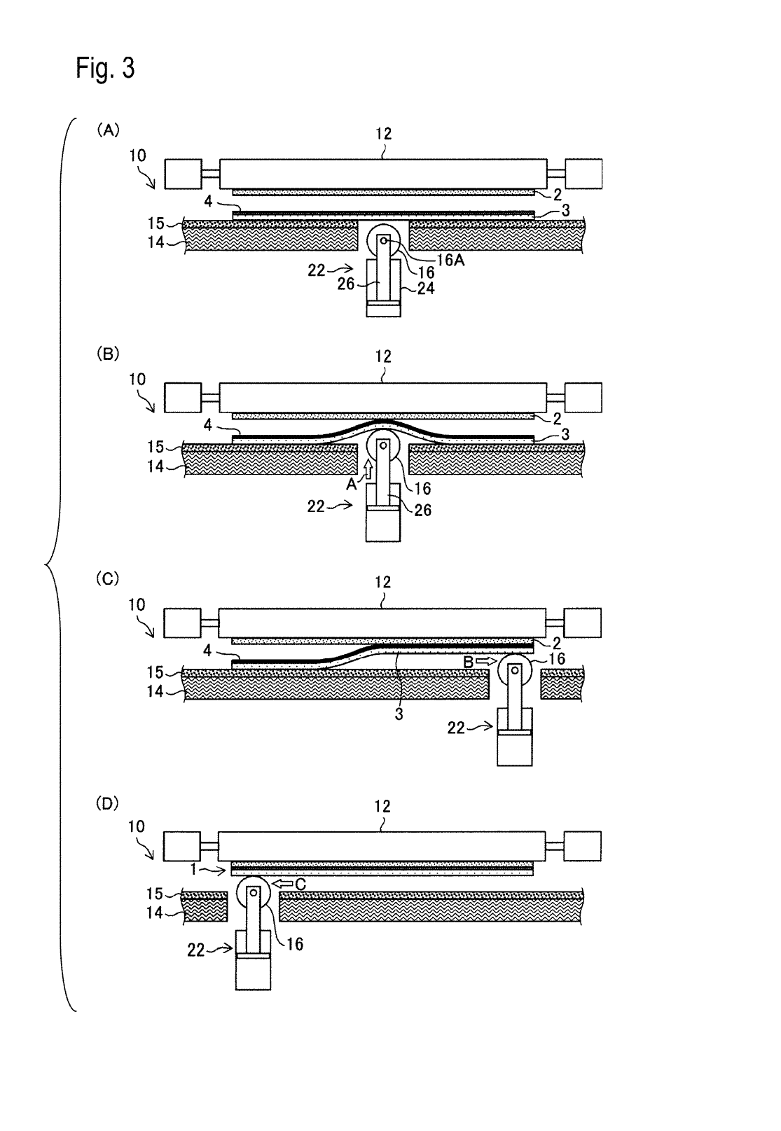

(A) to (D) of FIG. 3 are side views illustrating a main-portion configuration of a bonding device 10 used in a suction step and a bonding step which are included in a laminate manufacturing step, and are explanatory views illustrating movements in the bonding step in time series. In addition, a substrate suctioning device of this embodiment, used in the suction step, is mounted on the bonding device 10. The suctioning device will be described later.

<Bonding Device 10>

The bonding device 10 illustrated in (A) to (D) of FIG. 3 is a device that presses the reinforcing plate 3, in a state of bending-deformed with its own weight, against the substrate 2 by using the roller 16, and bonds the whole surface of the reinforcing plate 3 to the substrate 2 by a pressing force applied from the roller 16 while rotating the roller 16.

As in (A) of FIG. 3, the bonding device 10 includes an upper table (table) 12 that vacuum-suctions the substrate 2 on a lower surface, and a lower table 14 disposed on a lower side of the upper table 12 and on which the reinforcing plate 3 is placed on an upper surface thereof. The lower surface of the upper table 12 and the upper surface of the lower table 14 are set to parallel with each other. In addition, a resin sheet 15, which reduces friction with the reinforcing plate 3, is provided on the upper surface of the lower table 14, and the reinforcing plate 3 is placed on the resin sheet 15.

The arrangement of the substrate 2 and the reinforcing plate 3 may be performed in an opposite manner. That is, the substrate 2 may be placed on the lower table 14, and the reinforcing plate 3 may be suctioned to the upper table 12. In addition, it is preferable that the bonding device 10 includes a transport mechanism that delivers the substrate 2 and the reinforcing plate 3 to the upper table 12 and the lower table 14.

The bonding device 10 includes the roller 16 that comes into contact with a lower surface of the reinforcing plate 3 placed on the lower table 14 to allow the reinforcing plate 3 to be bending-deformed with its own weight, and a cylinder device 22 that presses the reinforcing plate 3, which has been bending-deformed by the roller 16, against the substrate 2 suctioned to the upper table 12.

The cylinder device 22 is constituted by a cylinder main body 24 and a rod 26 that protrudes from and retreats into the cylinder main body 24. The roller 16 is supported at a head of the rod 26 in a rotatable manner around the central axis 16A.

In addition, the bonding device 10 includes a movement mechanism (not illustrated) that integrally moves the lower table 14, the roller 16 and the cylinder device 22 parallel to the lower surface of the upper table 12 and in the horizontal direction.

As in (B) of FIG. 3, when the rod 26 protrudes, the roller 16 is raised in an arrow direction A, and comes into contact with the lower surface of the reinforcing plate 3 placed on the lower table 14 to allow the reinforcing plate 3 to be bending-deformed with its own weight. For example, the roller 16 is constituted by a metallic roller main body and a rubber sheet fixed to an outer peripheral surface of the roller main body so as to suppress damage of the reinforcing plate 3, and the rubber sheet comes into contact with the lower surface of the reinforcing plate 3.

The cylinder device 22 presses the reinforcing plate 3 which has been bending-deformed by the roller 16 against the substrate 2 suctioned to the upper table 12. That is, a load from the cylinder device 22 to the roller 16 is applied, and the reinforcing plate 3 is pressed against the substrate 2 through the roller 16 due to the load.

### [Bonding Method by Bonding Device 10]

As in (B) of FIG. 3, when bonding the substrate 2 and the reinforcing plate 3, the roller 16 is raised by the cylinder device 22 to bending-deform the reinforcing plate 3 placed on the lower table 14, and presses it against the substrate 2 suctioned to the upper table 12, from a lower side. Here, the reinforcing plate 3 is bonded to the substrate 2 in a bending-deformed state, and thus air bubbles are less likely to be entrapped between the substrate 2 and the reinforcing plate 3.

In this state, as in (C) of FIG. 3, the roller 16 is moved in an arrow direction B by the movement mechanism to bond a right half of the substrate 2 and a right half of the reinforcing plate 3 to each other. Then, as in (D) of FIG. 3, the roller 16 is moved in an arrow C direction to bond a left half of the substrate 2 and a left half of the reinforcing plate 3 to each other. Here, the roller 16 bonds the whole surface of the reinforcing plate 3 to the substrate 2 while rotating by friction with the lower surface of the reinforcing plate 3. According to this, the whole surface of the reinforcing plate 3 is bonded to the substrate 2, thereby manufacturing the laminate 1.

According to the bonding step illustrated in (A) to (D) of FIG. 3, the reinforcing plate 3 is merely placed on the lower table 14, and is not suction-fixed to the lower table 14. Accordingly, it is possible to bond the reinforcing plate 3 to the substrate 2 in a state in which a strain of the reinforcing plate 3 is small. According to this, it is possible to reduce warpage of the laminate 1 (refer to (D) of FIG. 3) after bonding. This effect is significant in a case where both of the substrate 2 and the reinforcing plate 3 include a glass plate.

For example, in a case of bonding a glass plate and a resin plate less rigid than the glass plate to each other, the rigidity of the resin plate is lower than the rigidity of the glass plate, and thus a strain occurs in the resin plate after bonding and it conforms to the glass plate. In contrast, a strain hardly occurs in the glass plate, and it is likely to be a flat plate shape. Accordingly, warpage of the laminate is less likely to occur. On the other hand, in a case of bonding glass plates to each other, a strain occurs in both glass plates after bonding and is less likely to conform to one of them. Therefore, warpage of a laminate is likely to occur.

As in (B) of FIG. 3, the roller 16 at the time of initiating bonding is disposed at a position that is equally distant from both edges of the reinforcing plate 3. However, it may be disposed in the vicinity of one edge of the reinforcing plate 3, and may be moved from the position toward the other edge to bond the whole surface of the reinforcing plate 3 to the substrate 2.

### [Configuration of Suctioning Device]

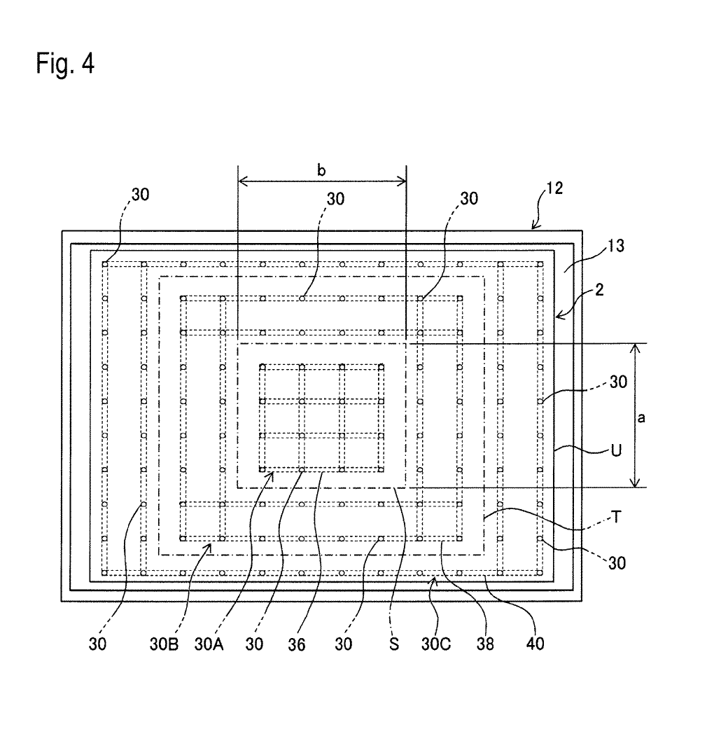

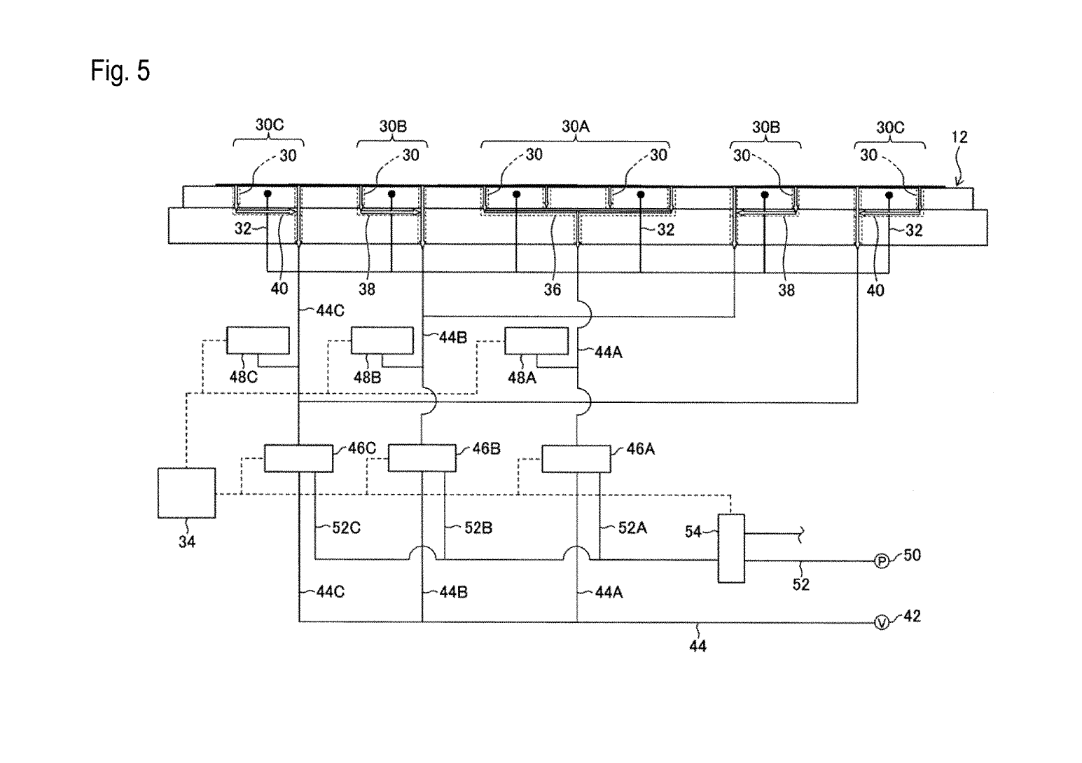

FIG. 4 is a plan view of the upper table 12 in which the substrate suctioning device of the present invention is applied to the upper table 12 of (A) to (D) of FIG. 3, and illustrates that a plurality of suction holes (suction units) 30 are disposed in an approximately whole surface of the suction surface 13 in a lattice pattern shape. FIG. 5 is a structure diagram of the upper table 12, illustrating a vacuum (suction) system and an air blowing system which are connected to the suction holes 30.

In FIG. 4 and FIG. 5, the upper table 12, which suctions the substrate 2 having a rectangular shape having longitudinal and lateral sizes of 880 mm×680 mm, is exemplified, but the size of the substrate 2 is not limited to the above-described size. In addition, in FIG. 4 and FIG. 5, the substrate 2 having a thickness of 0.2 mm or less is exemplified, but there is no limitation to the thickness. In addition, the upper table 12 is provided with the air blowing system, but one provided with only the vacuum system can be applied.

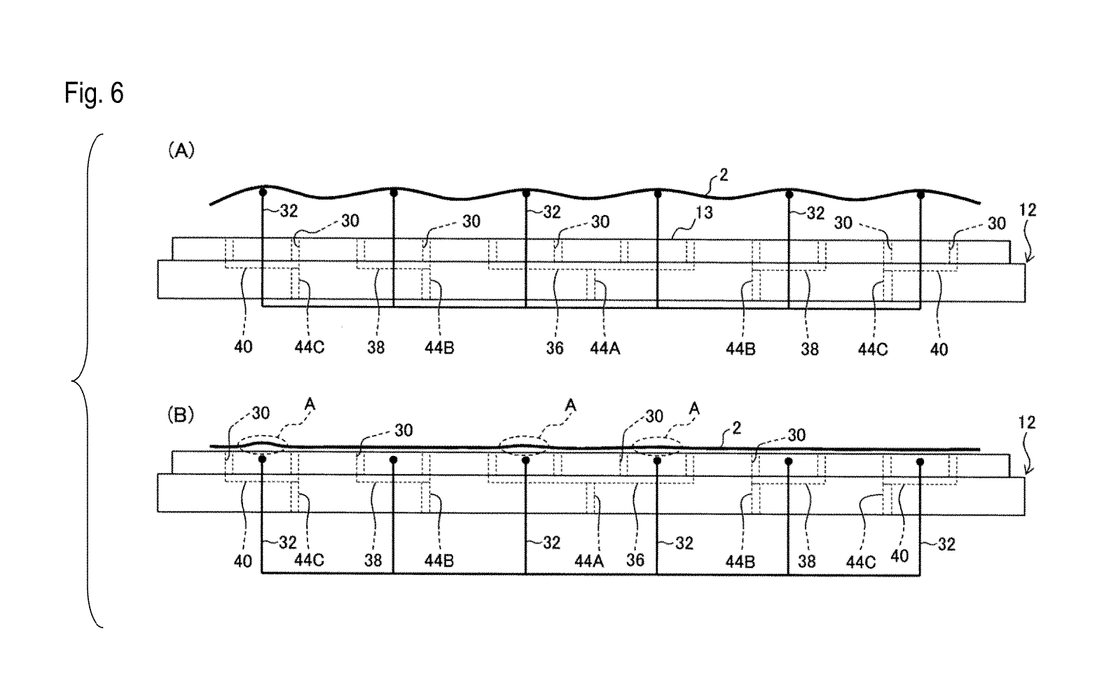

(A) of FIG. 6 is a side view of the upper table 12 which illustrates a state immediately before the substrate 2 conveyed from a transport mechanism (not illustrated) is placed on the suction surface of the upper table 12, and (B) is a side view of the upper table 12 in which the substrate 2 is placed on the suction surface 13 of the upper table 12.

As in (A) of FIG. 6, the upper table 12 is inverted so that the suction surface 13 faces an upper side before receiving the substrate 2. Then, when the substrate 2 is transferred to and placed on heads of a plurality of rods 32 that protrude from the suction surface 13, as in (B) of FIG. 6, the rods 32 are contracted to retreat from the suction surface 13. By this movement, the substrate 2 is placed on the suction surface 13. Here, the substrate 2 may be placed on the suction surface 13 in warped state due to warpage of the thin substrate itself, and warpage due to its own weight of the substrate 2 which occurs when the substrate 2 is placed on the heads of the rods 32. When the entirety of the substrate 2 is suctioned in this state, a multi-point placed portion is firstly suctioned, and the substrate 2 cannot move due to friction of the firstly suctioned portion. Therefore, as indicated by a broken line region A in (B) of FIG. 6, the substrate 2 is apt to be suctioned in a state of partially coming off. When bonding is performed in this state as in (A) to (D) of FIG. 3, a strain remains in a laminate after bonding, and thus there is a problem that warpage occurs in the laminate.

Accordingly, the upper table 12 of this embodiment is provided with the vacuum system and the air blowing system, and is provided with a control unit 34 (refer to FIG. 5) that controls the vacuum system and the air blowing system so as to reduce warpage illustrated in (B) of FIG. 6.

### [Division Structure of Suction Hole 30]

As in FIG. 4, the plurality of suction holes 30 are divided into three parts of suction hole groups 30A, 30B and 30C.

The suction hole group (a group of the suction holes) 30A is constructed in such a manner that a plurality of suction holes 30 disposed at the center of the suction surface 13 communicate with each other through four columns and four rows of ventilation passages 36 which communicate with each other. The central region S, which is surrounded by a one-dot chain line and is suctioned by the suction hole group 30A, in the substrate 2 is a primary suction region. A longitudinal length a thereof is set to approximately 550 mm and a horizontal length b thereof is set to approximately 670 mm.

A suction hole group (a plurality of remaining suction units) 30B is disposed in a frame shape to surround the suction hole group 30A, and is constructed in such a manner that a plurality of suction holes 30 communicate with each other through four columns and four rows of ventilation passages 38 which communicate with each other. A region T, which is surrounded by a one-dot chain line and is suctioned by the suction hole group 30B, in the substrate 2 is set as a secondary suction region. The secondary suction region is a region obtained by excluding the central region S from the region T.

A suction hole group (a plurality of remaining suction units) 30C is disposed in a frame shape to surround the suction hole group 30B, and is constructed in such a manner that a plurality of suction holes 30 communicate with each other through four columns and two rows of ventilation passages 40 which communicate with each other. A region U ranging up to an outer edge, which is suctioned by the suction hole group 30C, in the substrate 2 is set as a tertiary suction region. The tertiary suction region is a region obtained by excluding the central region S and the region T from the region U.

With regard to the substrate 2, when the primary suction region, the secondary suction region and the tertiary suction region are sequentially suctioned to the suction surface 13, the whole surface of the substrate 2 is suctioned and retained to the suction surface 13.

### [Vacuum System]

As in FIG. 5, the vacuum system includes a suction pump 42. A pipeline 44 is connected to the suction pump 42, and the pipeline 44 is branched into pipelines 44A, 44B and 44C. The pipeline 44A communicates with the ventilation passages 36 through a switching valve 46A such as a three-way valve, the pipeline 44B communicates with the ventilation passages 38 through a switching valve 46B, and the pipeline 44C communicates with the ventilation passages 40 through a switching valve 46C. In addition, the pipeline 44A is provided with a pressure meter 48A that detects an inner pressure of the pipeline 44A, the pipeline 44B is provided with a pressure meter 48B that detects an inner pressure of the pipeline 44B, and the pipeline 44C is provided with a pressure meter 48C that detects an inner pressure of the pipeline 44C.

Accordingly, according to the vacuum system, in a state in which the switching valves 46A, 46B and 46C are each switched to a closing position on a vacuum system side, when the suction pump 42 is driven and the switching valve 46A is opened, the suction holes 30 of the suction hole group 30A is decompressed through the pipeline 44A and the ventilation passages 36. According to this, the primary suction region of the substrate 2 is suctioned to the suction surface 13. In addition, when the switching valve 46B is opened, the suction holes 30 of the suction hole group 30B is decompressed through the pipeline 44B and the ventilation passages 38, and thus the secondary suction region of the substrate 2 is suctioned to the suction surface 13. In addition, when the switching valve 46C is opened, the suction holes 30 of the suction hole group 30C is decompressed through the pipeline 44C and the ventilation passages 40. According to this, the tertiary suction region of the substrate 2 is suctioned to the suction surface 13.

### [Air Blowing System]

As in FIG. 5, the air blowing system includes a compressed air supply pump (hereinafter, referred to as “supply pump”) 50. A pipeline 52 is connected to the supply pump 50, and the pipeline 52 is branched into pipelines 52A, 52B and 52C through an atmosphere-open switching valve (hereinafter, referred to as “switching valve”) 54. The pipeline 52A communicates with the ventilation passages 36 through the switching valve 46A, the pipeline 52B communicates with the ventilation passages 38 through the switching valve 46B, and the pipeline 52C communicates with the ventilation passages 40 through the switching valve 46C.

Accordingly, according to the air blowing system, in a state in which the switching valve 54 is switched to the supply pump 50 side, and the switching valve 46A is switched to the air blowing system side, when the supply pump 50 is driven, compressed air from the supply pump 50 is supplied to the suction holes 30 of the suction hole group 30A through the pipeline 44A and the ventilation passages 36. According to this, the compressed air is sprayed from the suction holes 30, and thus the primary suction region of the substrate 2 is air-blown.

In addition, when the switching valve 46B is switched to the air blowing system side, compressed air from the supply pump 50 is supplied to the suction holes 30 of the suction hole group 30B through the pipeline 44B and the ventilation passages 38. According to this, the compressed air is sprayed from the suction holes 30, and thus the secondary suction region of the substrate 2 is air-blown.

In addition, when the switching valve 46C is switched to the air blowing system side, compressed air from the supply pump 50 is supplied to the suction holes 30 of the suction hole group 30C through the pipeline 44C and the ventilation passages 40. According to this, the compressed air is sprayed from the suction holes 30, and thus the tertiary suction region of the substrate 2 is air-blown.

### [Control Unit 34]

The control unit 34 stores a pressure value, which indicates that the substrate 2 is reliably suctioned to the suction surface 13, and controls movements of the switching valves 46A, 46B and 46C on the basis of inner pressure (pressure) values, which are output from the pressure meters 48A, 48B and 48C, of the pipelines 44A, 44B and 44C.

Specifically, after switching the switching valve 46A to the vacuum system, when detecting that the inner pressure value, which is output from the pressure meter 48A, of the pipeline 44A reaches the pressure value, that is, when the primary suction region of the substrate 2 is reliably suctioned to the suction surface 13, the control unit 34 switches the switching valve 46B from the air blowing system to the vacuum system. In addition, when detecting that the inner pressure value, which is output from the pressure meter 48B, of the pipeline 44B reaches the pressure value, that is, when the secondary suction region of the substrate 2 is reliably suctioned to the suction surface 13, the control unit 34 switches the switching valve 46C from the air blowing system to the vacuum system.

That is, before the inner pressure value of the pipeline 44A reaches the pressure value, compressed air from the supply pump 50 is sprayed from the suction holes 30 of the suction hole groups 30B and 30C, and thus the secondary suction region and the tertiary suction region of the substrate 2 is air-blown. In addition, before the inner pressure value of the pipeline 44B reaches the pressure value, compressed air from the supply pump 50 is sprayed from the suction holes 30 of the suction hole group 30C, and thus the tertiary suction region of the substrate 2 is air-blown.

Furthermore, when the bonding step illustrated in (A) to (D) of FIG. 3 is terminated, the control unit 34 switches the switching valves 46A, 46B and 46C to the air blowing system, and switches the switching valve 54 to an atmosphere-open side so as to allow the decompression to return to the atmosphere, thereby releasing suction and retention of the laminate 1 by the upper table 12.

### [Action of Upper Table 12]

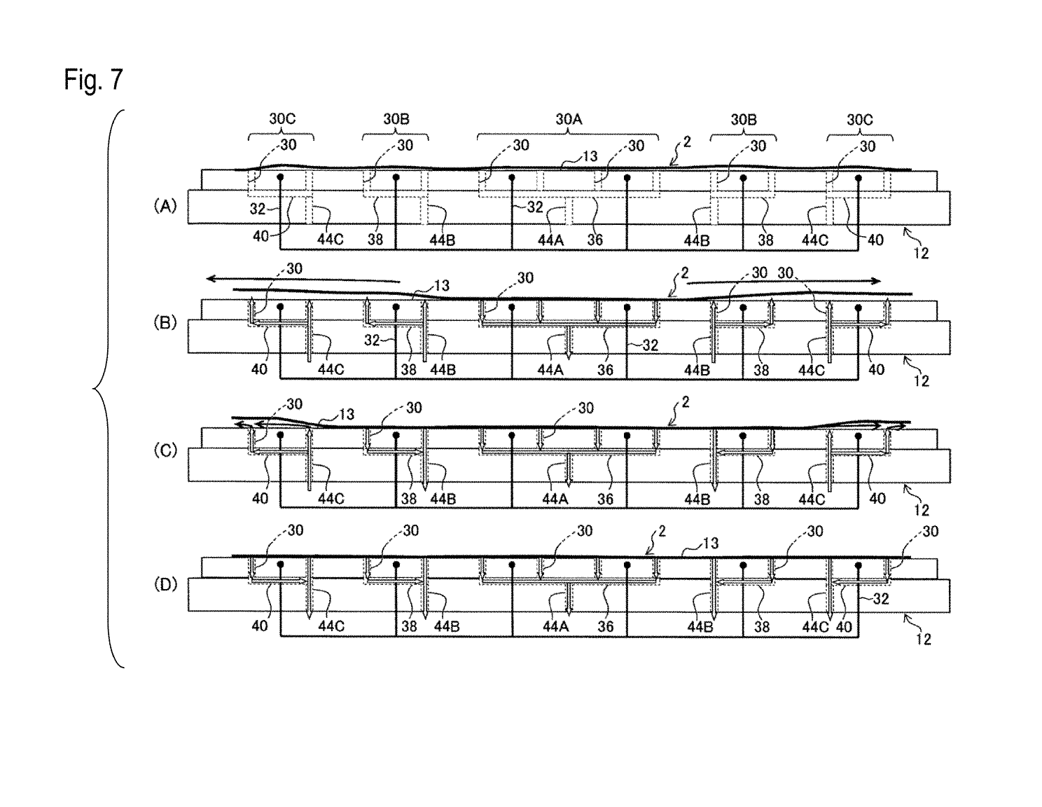

(A), (B), (C), and (D) of FIG. 7 are explanatory views illustrating in time series that the suction hole groups 30A, 30B and 30C are sequentially decompressed and the substrate 2 is sequentially suctioned onto the suction surface 13 of the upper table 12.

When the substrate 2 is placed on the suction surface 13 of the upper table 12 as in (A) of FIG. 7, first, as in (B) of FIG. 7, the control unit 34 switches the suction hole group 30A to the vacuum system for decompression. According to this, the primary suction region of the substrate 2 is suctioned to the suction surface 13. Next, when the primary suction region is reliably suctioned to the suction surface 13, as in (C) of FIG. 7, the control unit 34 drives the suction hole group 30B, which is disposed, with setting the suction hole group 30A as a starting point, in a direction away from the suction hole group 30A, by switching to the vacuum system. According to this, the secondary suction region of the substrate 2 is suctioned to the suction surface 13. Next, when the secondary suction region is reliably suctioned to the suction surface 13, as in (D) of FIG. 7, the control unit 34 decompresses the suction hole group 30C, which is disposed in a direction further away from the suction hole group 30A, by switching to the vacuum system. According to this, the tertiary suction region of the substrate 2 is suctioned to the suction surface 13, and the whole surface of the substrate 2 is reliably suctioned to the suction surface 13.

That is, the substrate 2, which is placed on the suction surface 13 of the upper table 12, is sequentially suctioned to the suction surface 13 in a ripple shape in a direction away from a central portion with the central portion corresponding to the suction hole group 30A set as a starting point, while correcting warpage of the substrate 2 itself to be flat, and the whole surface of the substrate 2 is suctioned to the suction surface 13. Accordingly, according to the upper table 12 of this embodiment, it is possible to improve a suction type of the substrate 2 with respect to the upper table 12, and thus it is possible to reduce warpage of the laminate 1 after bonding. In addition, it is possible to suppress occurrence of a non-suctioned portion caused by multi-point placing at initial placing time at which the substrate 2 is placed on the upper table 12.

In addition, the suction hole groups 30B and 30C also used as air spraying units for air blowing, and the suction hole groups 30B and 30C before driven to be switched to the vacuum system are switched to the air blowing system by the control unit 34.

According to this, the substrate 2 is sequentially suctioned by the suction hole groups 30B and 30C, which are switched to the vacuum system, while being air-blown by air sprayed from the suction hole groups 30B and 30C. When performing the air blowing as described above, it is possible to allow suction to proceed in a state of reducing friction, which is friction between the suction surface 13 of the upper table 12 and the substrate 2 and occurs in a case where the substrate 2 is multi-point placed on the suction surface 13. In a placing state as in (A) of FIG. 7, the suction hole group 30A may be used as an air spraying unit, and may be then switched to the vacuum system.

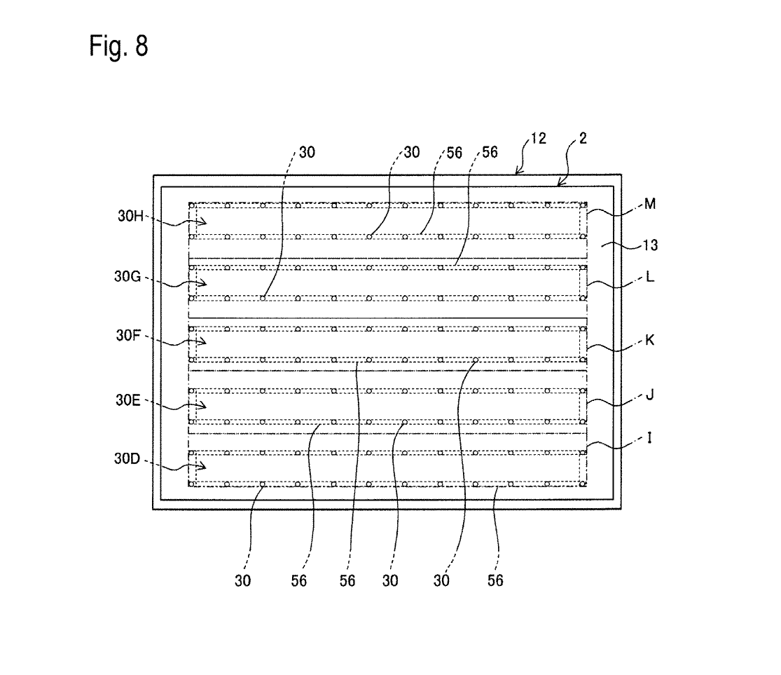

FIG. 8 is a plan view of the upper table 12 which illustrates another aspect of the upper table 12.

A plurality of suction holes 30 in the upper table 12 illustrated in FIG. 8 are divided into five parts of suction hole groups 30D, 30E, 30F, 30G, and 30H which are parallel to a long side of the upper table 12 having a rectangular shape.

In FIG. 8, the suction hole group (a group of the suction holes) 30D is constituted in such a manner that a plurality of suction holes 30, which are disposed in two rows along a lower side (the whole region of one side portion) of the suction surface 13, communicate with each other through a frame-shaped ventilation passage 56. A central region I, which is surrounded by a one-dot chain line and is suctioned by the suction hole group 30D, in the substrate 2 is a primary suction region.

Similarly, the suction hole groups (a plurality of remaining suction units) 30E, 30F, 30G, and 30H are constituted in such a manner that a plurality of suction holes 30, which are disposed in two rows along the lower side of the suction surface 13, communicate with each other through the frame-shaped ventilation passage 56. Central regions J, K, L, and M, which are surrounded by a one-dot chain line and are suctioned by the suction hole groups 30E, 30F, 30G, and 30H, in the substrate 2 are secondary suction region, a tertiary suction region, a quaternary suction region, and a quinary suction region, respectively.

With regard to the substrate 2, when the primary suction region to the quinary suction region are sequentially suctioned to the suction surface 13, the whole surface of the substrate 2 is suctioned and retained to the suction surface 13.

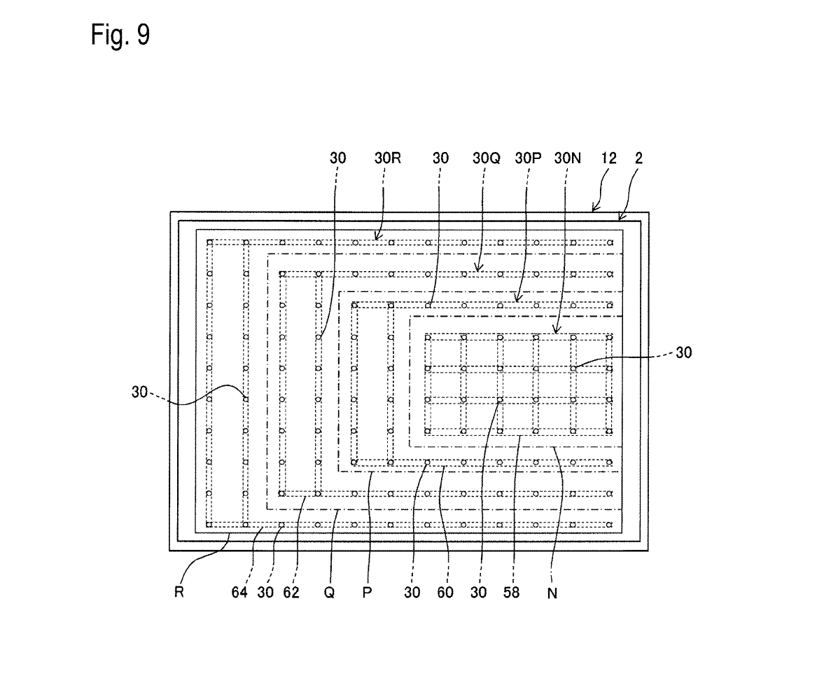

FIG. 9 is a plan view of the upper table 12 which illustrates still another aspect of the upper table 12.

As in FIG. 9, a plurality of suction holes 30 are divided into four parts of suction hole groups 30N, 30P, 30Q, and 30R.

The suction hole group (a group of the suction holes) 30N is constituted in such a manner that a plurality of suction holes 30, which are disposed at the center of a short side (a part of one side portion) of the suction surface 13, communicate with each other through six columns and four rows of ventilation passages 58 which communicate with each other. A central region N, which is surrounded by a one-dot chain line and is suctioned by the suction hole group 30N, in the substrate 2 is a primary suction region.

The suction hole group (a plurality of remaining suction units) 30P is disposed in a U-shape to surround the suction hole group 30N, and is constituted in such a manner that a plurality of suction holes 30 communicate with each other through two columns and two rows of ventilation passages 60 which communicate with each other. A region P, which is surrounded by a one-dot chain line and is suctioned by the suction hole group 30P, in the substrate 2 is set as a secondary suction region. The secondary suction region is a region obtained by excluding the region N from the region P.

The suction hole group (a plurality of remaining suction units) 30Q is disposed in a U-shape to surround the suction hole group 30P, and is constituted in such a manner that a plurality of suction holes 30 communicate with each other through two columns and two rows of ventilation passages 62 which communicate with each other. A region Q, which is surrounded by a one-dot chain line and is suctioned by the suction hole group 30Q, in the substrate 2 is set as a tertiary suction region. The tertiary suction region is a region obtained by excluding the regions N and P from the region Q.

The suction hole group (a plurality of remaining suction units) 30R is disposed in a U-shape to surround the suction hole group 30Q, and is constituted in such a manner that the plurality of suction holes 30 communicate with each other through two columns and two rows of ventilation passages 64 which communicate with each other. A region R ranging up to an outer edge, which is suctioned by the suction hole group 30R, in the substrate 2 is set as a quaternary suction region. The quaternary suction region is a region obtained by excluding the regions N, P, and R from the region R.

With regard to the substrate 2, when the primary suction region to the quaternary suction region are sequentially suctioned to the suction surface 13 in a ripple shape, the whole surface of the substrate 2 is suctioned and retained to the suction surface 13.

### [Characteristic of Bonding Device 10]

According to the bonding device 10 including the upper table 12 as in (A) to (D) of FIG. 3, it is possible to improve a suction type of the substrate 2 with respect to the upper table 12, and thus it is possible to reduce warpage of the laminate 1, which is caused by a suction step. In addition, in a bonding step also, it is possible to reduce warpage of the laminate 1, which is caused by the bonding step, due to an action of the roller 16 that allows the reinforcing plate 3 to be bending-deformed with its own weight.

### [Characteristics of Electronic Device Manufacturing Method]

The laminate manufacturing step of the electronic device manufacturing method includes the suction step and the bonding step of the bonding device 10, and thus it is possible to provide an electronic device manufacturing method capable of reducing warpage of the laminate 1 after bonding. In the laminate 1 manufactured by the laminate manufacturing step, warpage is reduced. Accordingly, it is possible to form a function layer with good quality on the front surface 2a of the substrate 2 in a function layer forming step.

Hereinbefore, an embodiment of the present invention has been described, but the present invention is not limited to the embodiment. Various modifications and changes can be made in a range of the gist of the present invention described in the claims.

For example, the bonding device 10 and the upper table 12 that is a suctioning device in this embodiment are used to manufacture the laminate 1 to be used in the electronic device manufacturing process, but the use of the bonding device 10 and the upper table 12 may be various.

The present application is based on a Japanese patent application No. 2014-220107 filed on Oct. 29, 2014, the content thereof being incorporated herein by reference.

### REFERENCE SIGNS LIST

1: Laminate
2: Substrate
2A: Substrate
2B: Substrate
6: Laminate
7: Function layer
10: Bonding device
12: Upper table
13: Suction surface
14: Lower table
16: Roller
22: Cylinder device
30: Suction hole
30A, 30B, 30C, 30D, 30E, 30F, 30G, 30H, 30N, 30P, 30Q, and 30R: Suction hole group
34: Control unit
42: Suction pump
46A, 46B and 46C: Switching valve
50: Supply pump
54: Switching valve

1. A substrate suctioning device comprising a table having a suction surface suctioning a substrate, and a plurality of suction units provided on the suction surface of the table,
wherein the substrate suctioning device comprises a control unit that, with setting a group of suction unit(s) among the plurality of suction units as a starting point, sequentially decompresses a plurality of remaining suction units disposed in a direction away from the group of suction unit(s) as the starting point, along the direction away.

2. The substrate suctioning device according to claim 1, wherein the control unit, with setting the group of suction unit(s) disposed in a central portion of the table having a rectangular shape as the starting point, sequentially decompresses the plurality of remaining suction units disposed in the direction away from the group of suction unit(s) set as the starting point, along the direction away.

3. The substrate suctioning device according to claim 1, wherein the control unit, with setting the group of suction unit(s) disposed along one side portion of the table having a rectangular shape as the starting point, sequentially decompresses the plurality of remaining suction units disposed in the direction away from the group of suction unit(s) set as the starting point, along the direction away.

4. The substrate suctioning device according to claim 1, wherein:
the plurality of suction units are also used as air spraying units; and
among the plurality of suction units, a suction unit before driven by the control unit is switched to the air spraying unit by the control unit.

5. A substrate bonding device that bonds a first substrate and a second substrate, comprising:
the substrate suctioning device described in claim 1, which suctions the first substrate by the table of the suctioning device; and
a roller that presses the second substrate in a state of bending-deformed with its own weight, against the first substrate, and bonds a whole surface of the second substrate to the first substrate while rotating.

6. A substrate bonding method of bonding a first substrate and a second substrate, comprising:
a suction step of suctioning and retaining the first substrate to the table of the substrate suctioning device described in claim 1; and
a bonding step of pressing the second substrate in a state of bending-deformed with its own weight, against the first substrate by a roller, and bonding a whole surface of the second substrate to the first substrate while rotating the roller.

7. An electronic device manufacturing method, comprising a laminate manufacturing step of manufacturing a laminate by bonding a first substrate and a second substrate, a function layer forming step of forming a function layer on an exposed surface of the first substrate in the laminate, and a separation step of separating the second substrate from the first substrate on which the function layer has been formed,
wherein the laminate manufacturing step comprises:
a suction step of suctioning and retaining the first substrate to the table of the substrate suctioning device described in claim 1; and
a bonding step of pressing the second substrate in a state of bending-deformed with its own weight, against the first substrate by a roller, and bonding a whole surface of the second substrate to the first substrate while rotating the roller.
